(19) United States
(12) Patent Application Publication
(10) Pub. No.: US 2019/0066794 A1
(43) Pub. Date: Feb. 28, 2019

(54) MEMORY SYSTEM AND OPERATING METHOD OF THE MEMORY SYSTEM

(71) Applicant: SK hynix Inc., Icheon-si Gyeonggi-do (KR)

(72) Inventor: Jong Woo KIM, Icheon-si Gyeonggi-do (KR)

(73) Assignee: SK hynix Inc., Icheon-si Gyeonggi-do (KR)

(21) Appl. No.: 16/027,699

(22) Filed: Jul. 5, 2018

(30) Foreign Application Priority Data
Aug. 24, 2017 (KR) 10-2017-0107234

(51) Int. Cl. G11C 16/10; G11C 16/26; G11C 16/14; G06F 3/06

(52) U.S. Cl. CPC G11C 16/10; G11C 16/26; G11C 16/14; G11C 16/0483; G06F 3/0659; G06F 3/0679; G06F 3/0604

(57) ABSTRACT

A memory system may include a memory controller transferring first and second logical page data to a memory device, wherein the memory device comprises a memory block including a plurality of physical pages into which the first and second logical page data are sequentially programmed, a first latch reading and temporarily storing programmed logical page data from a selected physical page when the program operation of the second logical page data fails during a program operation of the selected physical page, among the physical pages, a second latch temporarily storing the second logical page data, and an operation unit performing an operation of the programmed logical page data stored in the first latch and the second logical page data stored in the second latch to generate source data, and performing an operation of the source data and the original data to recover the first logical page data.

### CROSS-REFERENCE TO RELATED APPLICATION

The present application claims priority under 35 U.S.C. § 119(a) to Korean patent application number 10-2017-0107234 filed on Aug. 24, 2017, in the Korean Intellectual Property Office, the entire disclosure of which is incorporated by reference herein.

### BACKGROUND

### 1. Technical Field

Various embodiments relate generally to a memory system and a method of operating the same and, more particularly, to a memory system relating to performing a program operation and a method relating to operating the memory system.

### 2. Related Art

A memory system may include a memory device and a memory controller.

The memory device may store data or output the stored data. For example, the memory device may include a volatile memory device that loses stored date when a power supply is blocked, or a non-volatile memory device that retains the stored data even in the absence of the power supply.

The memory controller may control data communication between a host and the memory device.

The host may communicate with the memory device through the memory controller by using an interface protocol such as Peripheral Component Interconnect-Express (PCI-E), Advanced Technology Attachment (ATA), Serial ATA (SATA), Parallel ATA (PATA), or serial attached SCSI (SAS). However, the interface protocols provided for the purpose of data communication between the host and the memory system may not be limited to the above examples, and may include various other interface protocols such as a Universal Serial Bus (USB), a Multi-Media Card (MMC) an Enhanced Small Disk Interface (ESDI), or Integrated Drive Electronics (IDE).

### SUMMARY

According to an embodiment, a memory system may be provided. The memory system may include a memory controller sequentially transferring a program command, an address, a first logical page data and a second logical page data to a memory device, the memory controller temporarily storing original data of the first or second logical page data until a program operation of the first and second logical page data is completed, wherein the memory device comprises a memory block including a plurality of physical pages into which the first and second logical page data are sequentially programmed, a first latch reading and temporarily storing programmed logical page data from a selected physical page when the program operation of the second logical page data fails during a program operation of the selected physical page, among the physical pages, a second latch temporarily storing the second logical page data, and an operation unit performing an operation of the programmed logical page data stored in the first latch and the second logical page data stored in the second latch to generate source data, and performing an operation of the source data and the original data to recover the first logical page data.

According to an embodiment, a memory system may be provided. The memory system may include a memory device. The memory device may include a physical page configured to store least significant bit (LSB) data and most significant bit (MSB) data, store the LSB data in page buffers coupled to the physical page and perform a logical operation with the LSB data and the MSB data, and recover the LSB data. The memory system may include a memory controller configured to transfer commands to the memory device to recover the LSB data after a MSB program operation for programming the MSB data fails.

According to an embodiment, a method of operating a memory system may be provided. The method may include performing an LSB program operation to program a selected physical page with LSB data. The method may include reading the physical page and temporarily storing the LSB data. The method may include performing an MSB program operation to program the selected physical page with MSB data. The method may include generating source data by performing a logical operation of the LSB data and the MSB data when the MSB program operation fails. The method may include recovering the LSB data by performing a logical operation with original data of the MSB data and the source data.

According to an embodiment, a method of operating a memory system may be provided. The method may include, in a program operation during which selected memory cells are maintained at an erase state, or are programmed to a first program state, a second program state, or a third program state, performing an LSB program operation to increase threshold voltages of memory cells to be programmed into the second and third program states The method may include, in a program operation during which selected memory cells are maintained at an erase state, or are programmed to a first program state, a second program state, or a third program state, performing an MSB program operation to increase threshold voltages of memory cells to be programmed into the first to third program states The method may include, in a program operation during which selected memory cells are maintained at an erase state, or are programmed to a first program state, a second program state, or a third program state, generating source data by inverting data corresponding to the erase state and the first program state from the MSB data used in the MSB program operation when the MSB program operation fails The method may include, in a program operation during which selected memory cells are maintained at an erase state, or are programmed to a first program state, a second program state, or a third program state, recovering LSB data by performing a logical operation of the source data and original data of the MSB data.

### BRIEF DESCRIPTION OF THE DRAWINGS

FIG. 1 is a diagram illustrating a memory system according to an embodiment.

FIG. 2 is a diagram illustrating a memory controller illustrated in FIG. 1.

FIG. 3 is a diagram illustrating a memory device illustrated in FIG. 1.

FIGS. 4 to 6 are diagrams illustrating various embodiments of a memory block.

FIG. 7 is a flowchart illustrating a program operation according to an embodiment.

FIG. 8 is a flowchart illustrating a first data program operation illustrated in FIG. 7.

FIG. 9 is a flowchart illustrating a program and recovery operation illustrated in FIG. 7.

FIG. 10 is a diagram illustrating threshold voltage distributions of memory cells during a program operation.

FIG. 11 is a diagram illustrating a data recovery operation method according to an embodiment.

FIGS. 12 and 13 are diagrams illustrating embodiments of a memory controller and a memory device according to an embodiment.

FIGS. 14 and 15 are diagrams illustrating a method of operating a memory system according to an embodiment.

FIGS. 16 and 17 are diagrams illustrating a method of operating a memory system according to an embodiment.

FIG. 18 is a flowchart illustrating an embodiment of a program operation order according to an embodiment.

FIG. 19 is a flowchart illustrating an embodiment of a program operation order according to an embodiment.

FIG. 20 is a diagram illustrating an embodiment of a memory system including a memory controller illustrated in FIG. 2.

FIG. 21 is a diagram illustrating an embodiment of a memory system including a memory controller illustrated in FIG. 2.

FIG. 22 is a diagram illustrating an embodiment of a memory system including a memory controller illustrated in in FIG. 2.

FIG. 23 is a diagram illustrating an embodiment of a memory system including a memory controller illustrated in FIG. 2.

### DETAILED DESCRIPTION

Hereinafter, examples of embodiments will now be described hereinafter with reference to the accompanying drawings. However, they may be embodied in different forms and should not be construed as limited to the embodiments set forth herein. Rather, these embodiments are provided so that this disclosure will be thorough and complete, and will fully convey the scope of the examples of embodiments to those skilled in the art.

It will be understood that when an element is referred to as being “coupled” or “connected” to a certain element, it may be directly coupled or connected to the certain element or may be indirectly coupled or connected to the certain element, with intervening elements being present therebetween. In the specification, when an element is referred to as “comprising” or “including” a component, it does not exclude other components but may further include other components unless a description to the contrary is specifically pointed out in context.

Various embodiments may relate to a memory system capable of recovering previously programmed data when a program operation of the memory system fails, and an operating method thereof.

FIG. 1 is a diagram lustrating a memory system 1000 according to an embodiment.

Referring to FIG. 1, the memory system 1000 may include a semiconductor memory device 1100 storing data and a memory controller 1200 controlling the memory device 1100 in response to control of a host 2000.

The host 2000 may communicate with the memory system 1000 by using an interface protocol such as Peripheral Component Interconnect-Express (PCI-E), Advanced Technology Attachment (ATA), Serial ATA (SATA), Parallel ATA (PATA), or serial attached SCSI (SAS). In addition, the interface protocols provided for the purpose of data communication between the host 2000 and the memory system 1000 may not be limited to the above examples and may include various other interface protocols such as a Universal Serial Bus (USB), a Mult Media Card (MMC) an Enhanced Small Disk Interface (ESDI), or Integrated Drive Electronics (IDE).

The memory controller 1200 may control the general operations of the memory system 1000 and control a data exchange between the host 2000 and the memory device 1100. For example, the memory controller 1200 may convert received information so that commands, addresses and data may be communicated between the host 2000 and the memory device 1100, and may store and output the converted information. During a program operation, the memory controller 1200 may transfer commands, addresses, and data to the memory device 1100. When the program operation being performed by the memory device 1100 fails, the memory controller 1200 may transfer a command for recovering data programmed during a previous program operation to the memory device 1100. In addition, the memory controller 1200 may receive data necessary for a data recovery operation (for example, source data) and perform a logical operation to thereby recover the previous data. To perform the logical operation, the memory controller 1200 may include an operation unit.

The memory controller 1200 may control the memory device 1100 to perform a program, read, or erase operation. For example, the memory device 1100 may include a flash memory. During a program operation, the memory device 1100 may control the memory device 1100 so that logical page data may be stored in a selected physical page in response to the command, the address and the data from the memory controller 1200. In addition, when the program operation being performed fails, the memory device 1100 may recover the previously programmed logical page data in response to the command and the address received from the memory controller 1200. For example, when a program operation of most significant bit (MSB) data being performed fails, the memory device 1100 may recover the previously programmed least significant bit (LSB) data. For example, the memory device 1100 may receive the MSB data from the memory controller 1200 and perform a logical operation using the received MSB data to thereby recover the LSB data. To perform the above logical operation, the memory controller 1200 may include an operation unit.

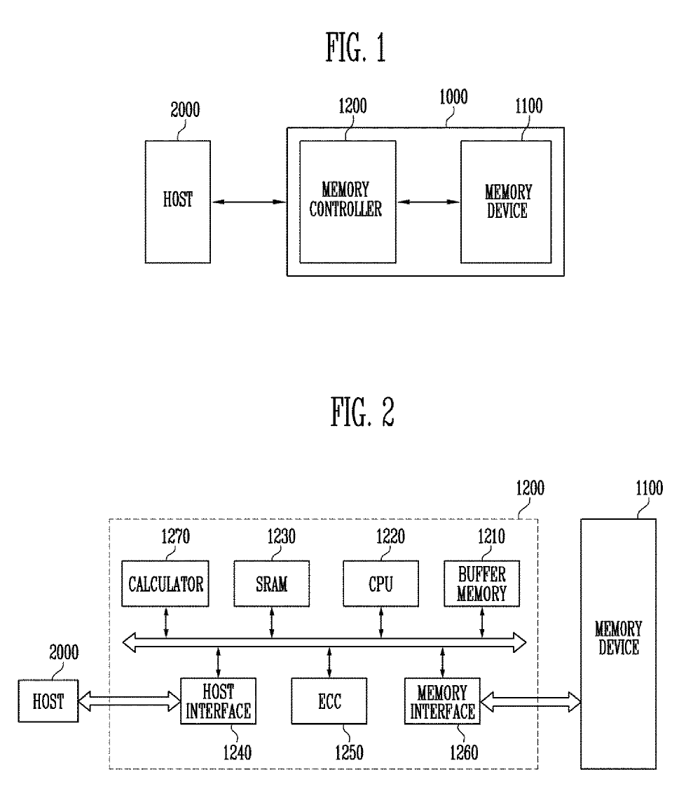

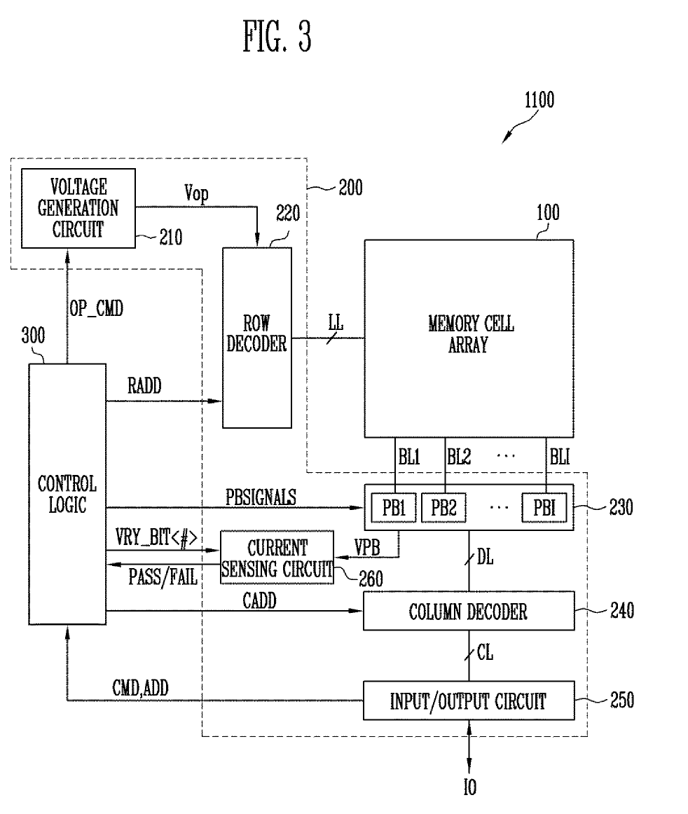

FIG. 2 is a diagram illustrating the memory controller 1200 illustrated in FIG. 1.

Referring to FIG. 2, in order to control communication between the host 2000 and the memory device 1100, the memory controller 1200 may include a buffer memory 1210, a central processing unit (CPU) 1220, a static random-access memory (SRAM) 1230, a host interface 1240, an error correction unit (ECC) 1250, and a memory interface 1260. In addition, the memory controller 1200 may further include a logical operation circuit 1270 as an operation unit. The logical operation circuit 1270 may be a calculator.

The buffer memory 1210 may temporarily store data when the memory controller 1200 controls the memory device 1100. For example, the buffer memory 1210 may store MSB data and source data during a data recovery operation and store recovered LSB data as a result of the data recovery operation.

The CPU 1220 may perform various operations or generate a command or an address to control the memory device 1100. For example, the CPU 1220 may generate various commands necessary to perform program, read and erase operations and a command for a data recovery operation.

The SRAM 1230 may function as a storage unit that stores various types of information for performing the operations of the memory controller 1200.

The host interface 1240 may include a data exchange protocol of the host 2000 connected to the memory system.

The ECC 1250 may be an error correction unit that detects and corrects errors during a program operation or a read operation.

The memory interface 1260 may include a protocol for exchanging various types of information with the memory device 1100.

When receiving the source data from the memory device 1100, the logical operation circuit 1270 may perform an XOR operation of the source data and original MSB data to recover the LSB data. For example, when the memory device 1100 performs the XOR operation of the source data and the original MSB data, the logical operation circuit 1270 may be removed from the memory controller 1200.

FIG. 3 is a diagram illustrating the memory device 1100 illustrated in FIG. 1.

Referring to FIG. 3, the memory device 1100 may include a memory cell array 100 in which data is stored. The memory device 1100 may include a peripheral circuit 200 configured to perform a program operation to store data in the memory cell array 100, a read operation to output the stored data, an erase operation to erase the stored data, or a data recovery operation. The memory device 1100 may include a control logic 300 that controls the peripheral circuits 200 in response to control of the memory controller 1200 illustrated in FIG. 1. In addition, the memory device 1100 may include an operation unit for recovering the previously programmed data during a program operation. For example, the operation unit of the memory device 1100 may include the control logic 300 and a page buffer group 230.

The memory cell array 100 may include a plurality of memory blocks. The memory blocks may store user data and various types of information for performing the operations of the memory device 100. The memory blocks may have a two-dimensional or three-dimensional structure.

The control logic 300 may control the peripheral circuits 200 to perform program, read, erase and data recovery operations in response to the control logic 300. For example, the peripheral circuits 200 may include a voltage generation circuit 210, a row decoder 220, the page buffer group 230, a column decoder 240, an input and output (input/output) circuit 250 and a current sensing circuit 260.

The voltage generation circuit 210 may generate various operating voltages Vop applied to perform program, read, erase, and data recovery operations in response to an operation signal OP_CMD. For example, the control logic 300 may control the voltage generation circuit 210 to generate a program voltage, a verify voltage, a pass voltage, a recovery program voltage, a read voltage, an erase voltage, and a turn-on voltage.

The row decoder 220 may transfer the operating voltages Vop to local lines LL coupled to a selected memory block, among the memory blocks of the memory cell array, in response to a row address RADD. The local lines LL may include local word lines, local drain select lines, and local source select lines. In addition, the local lines LL may include various lines coupled to a memory block, such as a source line.

The page buffer group 230 may be coupled to bit lines BL1 to BLI coupled in common to the memory blocks of the memory cell array 100. The page buffer group 230 may include a plurality of page buffers PB1 to PBI coupled to the bit lines BL1 to BLI, The page buffers PB1 to PBI may operate in response to page buffer control signals PBSIGNALS, For example, the page buffers PB1 to PBI may temporarily store data received through the bit lines BL1 to BLI, or sense a voltage or current in the bit lines BL1 to BLI during a read operation or a verify operation. In addition, the page buffers PB1 to PBI may perform an XOR operation of data in response to control of the control logic 300 during a data recovery operation. For example, the page buffers PB1 to PBI may include a plurality of latches. When first data and second data are stored in different latches, an XOR operation between the first data and the second data may be performed through data transfer between the latches, and data corresponding to the XOR operation result may be stored in the latches storing the first or second data, or different latches.

The column decoder 240 may transfer data between the input and output (input/output) circuit 250 and the page buffer group 230 in response to a column address CADD. For example, the column decoder 240 may exchange data with the page buffers PB through data lines DL, or exchange data with the input/output circuit 250 through column lines CL.

The input/output circuit 250 may transfer the command CMD and the address ADD from the memory controller 1200 illustrated in FIG. 1 to the control logic 300 through input/output lines IO, or exchange data DATA with the column decoder 240.

The current sensing circuit 260 may generate a reference current in response to an allowable bit VRY_BIT<#> and compare a sensing voltage VPB received from the page buffer group 230 with a reference voltage generated by the reference current to output a pass signal PASS or a fail signal FAIL during a read operation or a verify operation.

The control logic 300 may output the operation signal OP_CMD, the row address RADD, the page buffer control signals PBSIGNALS and the allowable bit VRY_BIT<#> to control the peripheral circuits 200 in response to the command CMD and the address ADD. In addition, the control logic 300 may determine whether a verify operation passes or fails in response to the pass or fail signal PASS or FAIL. In addition, the control logic 300 may control the peripheral circuits 200 to perform a data recovery operation in response to a recovery command when a program operation of second data fails after a program operation of first data is performed. The first and second data may be logical page data that is stored in a single physical page.

During the data recovery operation, the control logic 300 may control the peripheral circuits 200 to read the first data previously programmed in the selected page, generate source data by performing a logical operation of the read first data and the second data on which the program operation is interrupted, and recover the first data by receiving the original second data from the memory controller 1200 and performing a logical operation of the source data and the original second data. To perform the above logical operation as, the control logic 300 may include an operation control circuit 310 as illustrated in FIG. 12.

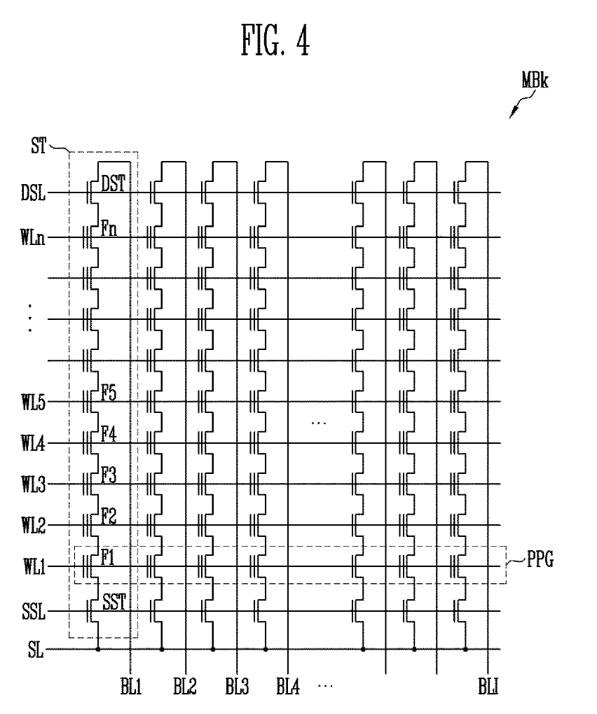

FIGS. 4 to 6 are diagrams illustrating various embodiments of a memory block.

Referring to FIG. 4, the memory cell array 100 of FIG. 3 may include a plurality of memory blocks. One (MBk) of the plurality of memory blocks will be described as an example with reference to FIG. 4.

The memory block MBk may include a plurality of cell strings ST coupled between the bit lines BL1 to BLI and a source line SL. For example, the cell strings ST may be coupled to the bit lines BL1 to BLI, respectively, and may be commonly coupled to the source line SL. Since the cell strings ST have similar structures to each other, the cell string ST coupled to the first bit line BL1 will be described as an example.

The cell string ST may include a source select transistor SST, first to nth memory cells F1 to Fn and a drain select transistor DST that are coupled in series between the source line SL and the first bit line BL1. The number of source and drain select transistors SST and DST may not be limited to that illustrated in FIG. 4. The source select transistor SST may be coupled between the source line SL and the first memory cell F1. The first to nth memory cells F1 to MCn may be coupled in series between the source selection transistor SST and the drain selection transistor DST. The drain select transistor DST may be coupled between the nth memory cell Fn and the first bit line BL1. Though not illustrated in FIG. 4, dummy cells may be further coupled between the memory cells F1 to Fn or between the source select transistor SST and the drain select transistor DST.

Gates of the source select transistor SST included in different cell strings may be coupled to a source select line SSL, gates of the first to nth memory cells F1 to Fn may be coupled to first to nth word lines WL1 to WLn, and gates of the drain select transistors DST may be coupled to drain select lines DSL. A group of memory cells coupled to each of the word lines WL1 to WLn may be referred to as a physical page PPG. For example, a group of the first memory cells F1 coupled to the first word line WL1, among the memory cells F1 to Fn included in different cell strings ST, may be the single physical page PPG. According to a program operation using a multi level cell (MLC) method, the single physical page PPG may include a plurality of logical pages. For example, the single physical page PPG may include first data and second data. The first data may be least significant bit (LSB) data and the second data may be most significant bit (MSB) data.

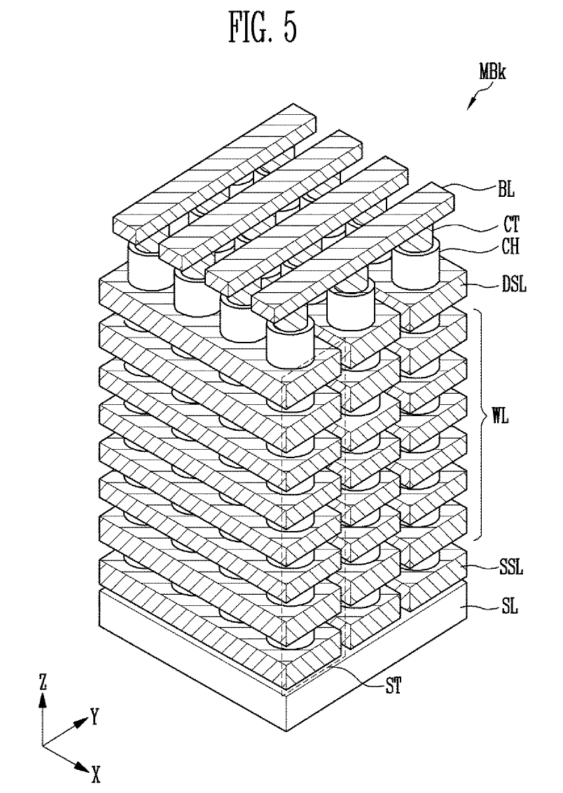

Referring to FIG. 5, the memory block MBk may have a three-dimensional structure.

The memory block MBk having the three-dimensional structure may have an I shape vertical (Z direction) to a substrate and include the plurality of cell strings ST arranged between the bit lines BL and the source line SL. Alternatively, a well may be formed instead of the source line SL. The structure of this memory string may be referred to as a Bit Cost Scalable (BiCS). For example, when the source line SL is formed in a horizontal direction to a top of the substrate, the cell strings ST having the BiCS structure may be formed in a vertical direction (Z direction) to a top of the source line SL.

For example, each of the cell strings ST may be arranged in a first direction (X direction) or a second direction (Y direction). The cell strings ST may include the source select lines SSL, the word lines WL, and the drain select lines DSL. The numbers of source select lines SSL, word lines WL and drain select lines DSL may not be limited to those illustrated in FIG. 5 and vary according to each memory device 1100. The cell strings ST may include vertical channel layers CH and the bit lines BL. The vertical channel layers CH may vertically pass through the source select lines SSL, the word lines WL and the drain select lines DSL. The bit lines BL may contact top portions of the vertical channel layers CH protruding above top portions of the drain select lines DSL and extend in the second direction (Y direction). The memory cells may be formed between the word lines WL and the vertical channel layers CH. Contact plugs CT may be further formed between the bit lines BL and the vertical channel layers CH.

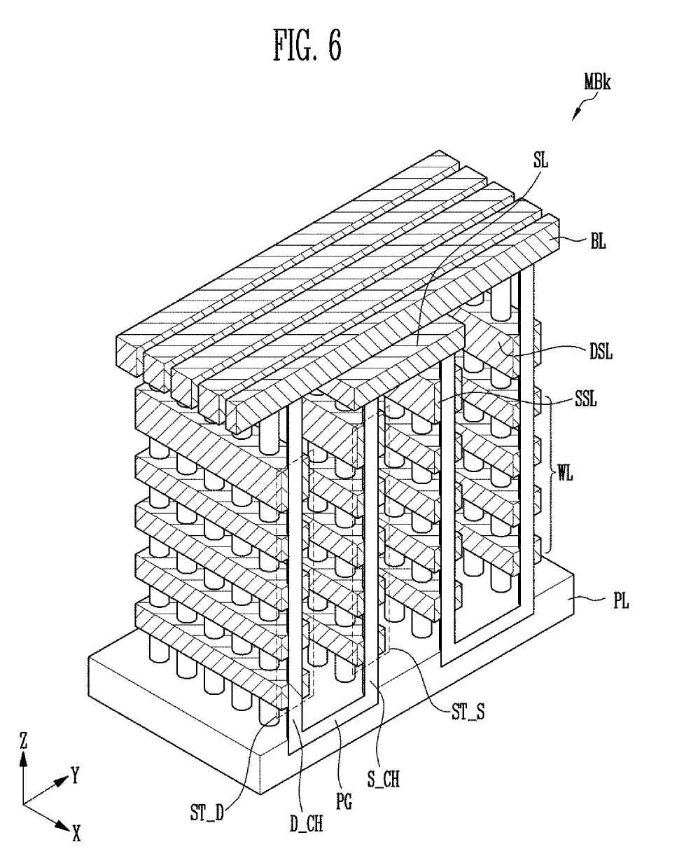

Referring to FIG. 6, the memory block MBk may have a three-dimensional structure that is different from that of FIG. 5.

The memory block MBk having the three-dimensional structure may have a u shape in the vertical direction (Z direction) to the substrate and include source strings ST_S and drain strings ST_D coupled between the bit lines BL and the source line SL and arranged in pairs. The source strings ST_S and the drain strings ST_D may be coupled to each other through a pipe gate PG to form the U-shaped structure. The pipe gate PG may be formed in a pipe line PL. For example, the source strings STS may be vertically formed between the source lines structure SL and the pipe line PL, and the drain strings ST_D may be vertically formed between the bit lines BL and the pipe line PL. This structure of the above cell string may be referred to as a Pipe-shaped Bit Cost Scalable (P-BiCS) structure.

For example, the drain strings STD and the source strings ST_S may be arranged in the first direction (X direction) and the second direction (Y direction), respectively, and the drain strings ST_D and the source strings ST_S may be alternately arranged. The drain strings ST_D may include the word lines WL and the drain select line DSL stacked on and separated from each other, and drain vertical channel layers D_CH vertically penetrating the word lines WL and the drain select line DSL. The source strings ST_D may include the word lines WL and the source select line SSL stacked on and separated from each other, and source vertical channel layers S_CH vertically penetrating the word lines WL and the source select line DSL. The drain vertical channel layers D_CH and the source vertical channel layers S_CH may be coupled to each other through the pipe gate PG in the pipe line PL. The bit lines BL may contact top portions of the drain vertical channel layers DCH protruding above the drain select line DSL and extend in the second direction (Y direction).

The memory blocks MBk may have various other structures in addition to the structures described with reference to FIGS. 4 to 6.

FIG. 7 is a flowchart illustrating a program operation according to an embodiment.

Referring to FIG. 7, a program operation according to an embodiment may be performed using a multi level cell (MLC) method by which 2-bit data may be stored in a single memory cell. According to the MLC method, two logical page data may be stored in a single physical page. For example, the logical page data may include less significant bit (LSB) data and most significant bit (MSB) data. Hereinafter, the LSB data may be referred to as first data and the MSB data may be referred to as second data.

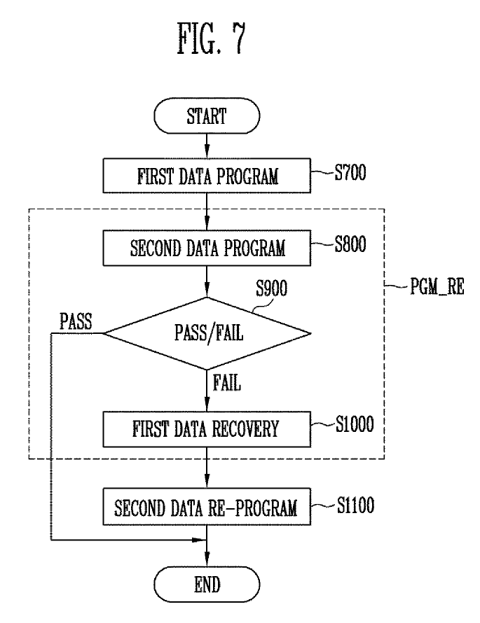

When a program operation of a selected physical page starts, a program operation (S700) of the first data may be performed. A method of performing the program operation (S700) of the first data will be described below with reference to FIG. 8. When the program operation (S700) of the first data is completed, a program operation (S800) of the second data may start, to be performed. The memory device 1100 may receive the second data from the memory controller 1200 and program the received second data into the selected physical page (S800).

When the program operation (S800) of the second data is completed (pass) without failure (S900), the program operation of the selected physical page may be completed. When the program operation (S800) of the second data fails, a recovery operation (S1000) of the previously programmed first data may be performed. A pass/fail determination operation (S900) of the program operation (S800) of the second data may not be performed while the program operation of the second data is being performed. Rather, when the program operation (S800) of the second data is completed without failure, it may be determined as a pass, and when failure occurs during the program operation (S800) of the second data, it may be determined as a fail. When the program operation (S800) of the second data fails, the recovery operation (S1000) of the first data may be performed. The recovery operation of the first data may be performed since the program operation of the second data is performed by combining the first data and the second data. In other words, when the program operation (S800) of the second data starts, since the first data stored in the memory cells may be changed, the recovery operation of the first data may be performed to re-perform the program operation of the second data. The program operation (S800) of the second data may fail for several reasons. For example, the program operation (S800) of the second data may fail due to a sudden power off or the like.

According to this embodiment, the recovery operation (S1000) of the first data may be performed according to an algorithm method, and a data recovery method will be described below.

When the recovery operation (S1000) of the first data is completed, the re-program operation (S1100) of the second data may start to be performed. For example, the re-program operation (S1100) of the second data may be performed by combining the recovered first data and the second data.

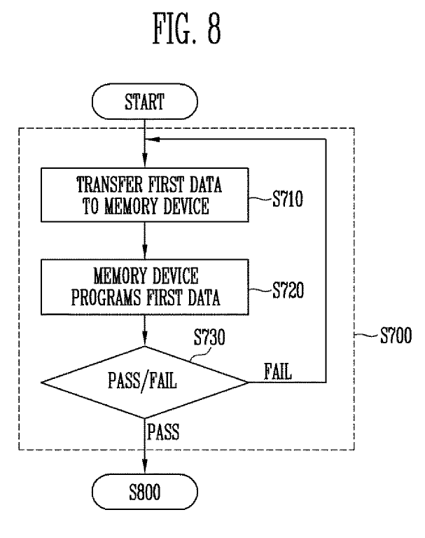

Among the above-described operations, a method of performing a program and recovery operation PGM_RE including the program operation (S800) of the second data, the pass/fail determination operation (S900), and the first data recovery operation (S1000) will be described below with reference to FIG. 9.

FIG. 8 is a flowchart illustrating a first data program operation illustrated in FIG. 7.

Referring to FIG. 8, when the program operation of the selected physical page starts, the memory controller 1200 illustrated in FIG. 1 may transfer the first data corresponding to LSB data to the memory device 1100 illustrated in FIG. 1 (S710). The first data may be temporarily stored in a storage device of the memory controller 1200, The memory device 1100 may program the received first data into the selected physical page (S720). The program operation of the first data may be performed using an Incremental Step Pulse Program (ISPP) method.

When the program operation of the first data fails as a result of a pass/fail determination operation (S730), the operations S710 to S730 may be repeated until the program operation of the first data passes.

When the program operation of the first data passes as a result of the pass/fail determination operation (S730), the program operation of the first data may be terminated, and the program operation (S800) of the second data may be performed.

The first data temporarily stored in the memory controller 1200 may be erased.

FIG. 9 is a flowchart illustrating operations of the program and recovery operation illustrated in FIG. 7.

Referring to FIG. 9, the program and recovery operation PGM_RE of FIG. 7 may include the program operation (S800) of the second data, the pass/fail determination operation (S900) and the recovery operation (S1000) of the first data.

When the program operation (S800) of the second data starts, a read operation (S810) of the first data may be performed on the selected physical page so as to combine the first data and the second data. For example, the read first data may be temporarily stored in the memory device (page buffers PB1 to PBI of FIG. 3). For example, the first data may be temporarily stored in the first latches of the page buffers PB1 to PBI.

Subsequently, the second data may be transferred to the memory device 1100 of FIG. 1 from the memory controller 1200 of FIG. 1 (S820). For example, the second data from the memory device 1100 may be temporarily stored in the second latches of the page buffers PB1 to PBI.

After completely receiving the second data, the memory device 1100 may perform a program operation of the second data by combining the first and second data (S830).

When the program operation (S800) of the second data is completed without failure (pass) (S900), the program operation of the selected physical page may be terminated.

However, when the program operation (S800) of the second data fails, the recovery operation (S1000) of the previously programmed first data may be performed.

When the recovery operation (S1000) of the first data starts, source data may be generated by performing a logical operation of the first and second data temporarily stored in the page buffers PB1 to PBI (S1010). For example, the source data may be a resultant obtained by performing an XOR operation of the first and second data. The source data may be temporarily stored in the second latches of the page buffers PB1 to PBI. In other words, although the second data is temporarily stored in the second latches of the page buffers PB1 to PBI during the program operation (S800), since the source data generated by performing the XOR operation of the first and second data during the recovery operation of the first data is stored, the original second data may be deleted from the second latches of the page buffers PB1 to PBI, and the source data may be temporarily stored.

Subsequently, the memory device 1100 may receive the original second data from the memory controller 1200 again (S1020). The original second data re-transferred to the memory device 1100 may be temporarily stored in third latches of the page buffers PB1 to PBI.

The memory device 1100 may perform a logical operation of the source data and the re-transferred original second data to thereby recover the first data. For example, the recovered first data may be a resultant obtained by performing an XOR operation of the source data and the re-transferred original second data. The recovered first data may be temporarily stored in the first latches of the page buffers PB1 to PBI. The recovered first data may be temporarily stored in other latches of the page buffers PB1 to PBI.

When the first data is recovered, the re-program operation (S1100) of the second data may be performed by combining the recovered first data and the second data. In an embodiment, for example, the recovered first data may be stored in the first latches of the page buffers PB1 to PBI. For example, the read data of step S810 may be erased from the first latches prior to storing the recovered first data within the first latches.

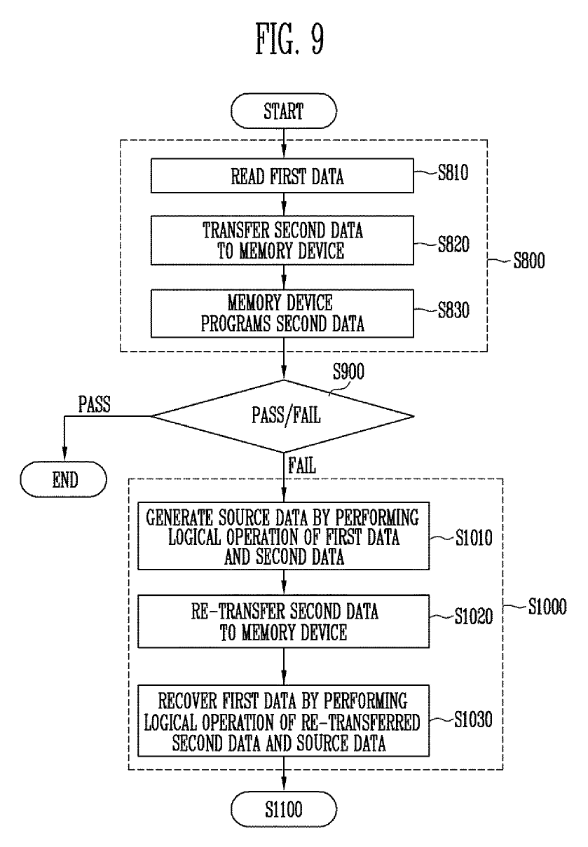

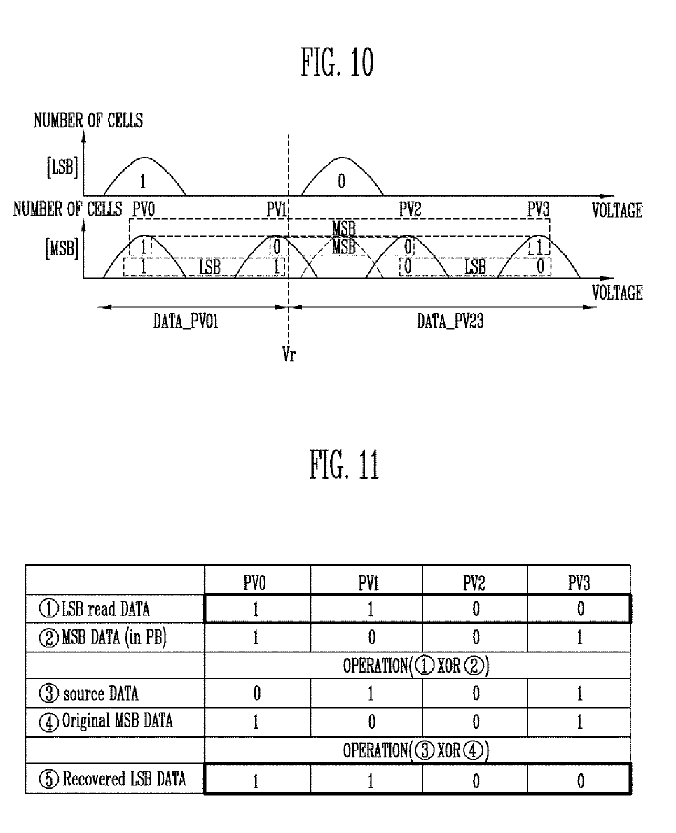

FIG. 10 is a diagram illustrating threshold voltage distributions of memory cells during a program operation.

Referring to FIG. 10, as for a multi level cell (MLC) storing a plurality of bits, a plurality of logical page data may be stored in a single physical page. For example, the LSB data and the MSB data may be stored in a single physical page. In the multi level cell (MLC), unselected memory cells may be maintained at an erase state PV0 and selected memory cells may be programmed into a first program state PV1, a second program state PV2 and a third program state PV3 according to threshold voltage distributions. For example, the first program state PV1 may have a greater threshold voltage than the erase state PV0, the second program state PV2 may have a greater threshold voltage than the first program state PV1, and the third program state PV3 may have a greater threshold voltage than the second program state PV2.

The program operation of the selected physical page may be performed in such a manner that a less significant bit (LSB) program operation may start first, and a most significant bit (MSB) program operation may be performed by combining the LSB data and the MSB data after the LSB program operation is completed.

When the LSB program operation is performed, threshold voltages of selected memory cells, among the memory cells having the erase state PV0, may increase. For example, during the LSB program operation, memory cells to be programmed into the second and third program states PV2 and PV3 may increase, and memory cells to be programmed into the erase state PV0 and the first program state PV1 may be maintained at the erase state PV0. During the LSB program operation, the memory cells having the erase state PV0 may have data ‘1’, and the programmed memory cells may have data ‘0’. The LSB program operation may be performed using an Incremental Step Pulse Program (ISPP) method. The MSB program operation may be performed when the LSB program operation is completed.

The MSB program operation may be performed using an ISPP method. The MSB program operation may be performed so that selected memory cells, among the memory cells having the erase state PV0, may have the first program state PV1, and the LSB programmed memory cells may have the second or third program state PV2 or PV3. When the MSB program operation is normally completed, the memory cells of the selected physical page may be programmed into the erase state PV0 or the first program state PV1, the second program state PV2 and the third program state PV3. The memory cells programmed into the erase state PV0 may have data ‘11’, the memory cells programmed into the first program state PV1 may have data ‘10’, the memory cells programmed into the second program state PV2 may have data ‘00’, and the memory cells programmed into the third program state PV3 may have data ‘01’.

Since the LSB data is stored in the memory controller 1200 until the LSB program operation finishes, even when the LSB program operation fails, the LSB program operation may be re-performed using the LSB data stored in the memory controller 1200.

However, since the memory controller 1200 stores only the MSB data without storing the LSB data during the MSB program operation, it may be difficult to recover the LSB data when the MSB program operation fails. When the MSB program operation starts, threshold voltages of the memory cells on which the program operation is performed may change. Thus, the original LSB data may not be obtained even when the LSB data is read.

In addition, although the memory controller 1200 may maintain the LSB data during the MSB program operation, the size of the memory controller 1200 may increase since the internal storage device of the memory controller 1200 may increase. For example, a size increase of the SRAM 1230 illustrated in FIG. 2 included in the memory controller 1200 may be avoided. Therefore, in this embodiment, the LSB data may be recovered without increasing the size of the memory controller 1200.

When the MSB program operation is stopped since the MSB operation fails, the threshold voltages of the memory cells being programmed into the first to third program states PV1 to PV3 may be distributed over an unclear range. When a read operation using a read voltage Vr is performed, the memory cells being programmed into the first program state PV1 may be output as data where ‘1’ and ‘0’ are mixed.

Thus, in this embodiment, the read operation using the read voltage Vr may be performed to temporarily store the LSB data before the MSB program operation is substantially performed. For example, the memory device 1100 may store data DATA_PV01 of memory cells having lower threshold voltages than the read voltage Vr as ‘1’ and data DATA_PV23 of memory cells having higher threshold voltages as ‘0’. The LSB data may be recovered by performing a logical operation of the read LSB data and the MSB data. A data recovery method will be described below.

FIG. 11 is a diagram illustrating a data recovery operation method according to an embodiment.

Referring to FIG. 11, before a most significant bit (MSB) program operation is substantially performed, least significant bit (LSB) data may be read (LSB read DATA) and temporarily stored in the page buffers PB1 to PBI (\textcircled{1}). For example, LSB data of memory cells to be programmed into the erase state PV0 and the first program state PV1 may be read as ‘1’, and LSB data of the memory cells to be programmed into the second or third program state (PV2 or PV3) may be read as ‘0’. The LSB read DATA (\textcircled{1}) may be stored in the first latches of the page buffers PB1 to PBI.

Even when the MSB program operation fails, the MSB data (MSB DATA) of the page buffers PB1 to PBI may be maintained (\textcircled{2}). For example, the MSB DATA (\textcircled{2}) may be stored in the second latches of the page buffers PB1 to PBI.

Therefore, when the MSB program operation fails, the memory device 1100 may perform a logical operation of the LSB read DATA \textcircled{1} and the MSB DATA \textcircled{2} maintained in the page buffers PB1 to PBI to generate source DATA \textcircled{3}. For example, the source DATA \textcircled{3} may be generated by performing an XOR operation of the LSB read DATA \textcircled{1} and the MSB DATA \textcircled{2} and may be stored in the second latches of the page buffers PB1 to PBI. For example, since the LSB data having the erase state PV0 is ‘1’ and the MSB data is ‘1,’ the source DATA \textcircled{3} having the erase state PV0 may be ‘0’ by performing the XOR operation of the LSB and MSB data. In this manner, the source DATA \textcircled{3} corresponding to each of the first to third program states PV1 to PV3 may be generated. When the XOR operation is performed as described above, the source DATA may have inversion data with respect to the data corresponding to the erase state PV0 and the first program state PV1 in the MSB DATA \textcircled{2}, and may be the same as the data corresponding to the second and third program states PV2 and PV3. In other words, the source DATA \textcircled{3} may be generated by inverting the data corresponding to the erase state PV0 and the first program state PV1 in the MSB DATA \textcircled{2}.

In this embodiment, since the source DATA \textcircled{3} may be stored again in the second latches storing the MSB DATA, the MSB DATA \textcircled{2} stored in the second latches may be lost, so that the size increase of the page buffers PB1 to PBI may be prevented. In other words, the size of the page buffers PB1 to PBI may increase as the number of latches included in the page buffers PB1 to PBI increases. However, in this embodiment, since the number of latches included in the page buffers PB1 to PBI is not limited, the source DATA \textcircled{3} may be stored in latches different from the second latches storing the MSB data \textcircled{2}. Hereinafter, according to an embodiment, a description will be made on the basis of the case where the source DATA \textcircled{3} is stored in the second latches.

When the source DATA \textcircled{3} is stored in the second latches, the memory device 1100 may receive Original MSB DATA from the memory device 1200 and temporarily store the Original MSB DATA in the page buffers PB1 to PBI (\textcircled{4}). The Original MSB DATA may be stored in the third latches of the page buffers PB1 to PBI. Subsequently, the memory device 1100 may recover the LSB data by performing a logical operation of the source DATA \textcircled{3} stored in the page buffers PB1 to PBI and the Original MSB data \textcircled{4} (\textcircled{5}). For example, the memory device 1100 may recover the LSB data by performing an XOR operation of the source DATA \textcircled{3} and the Original MSB data \textcircled{4} (\textcircled{5}) The recovered LSB DATA \textcircled{5} may be output to the memory controller 1200 for the MSB program operation.

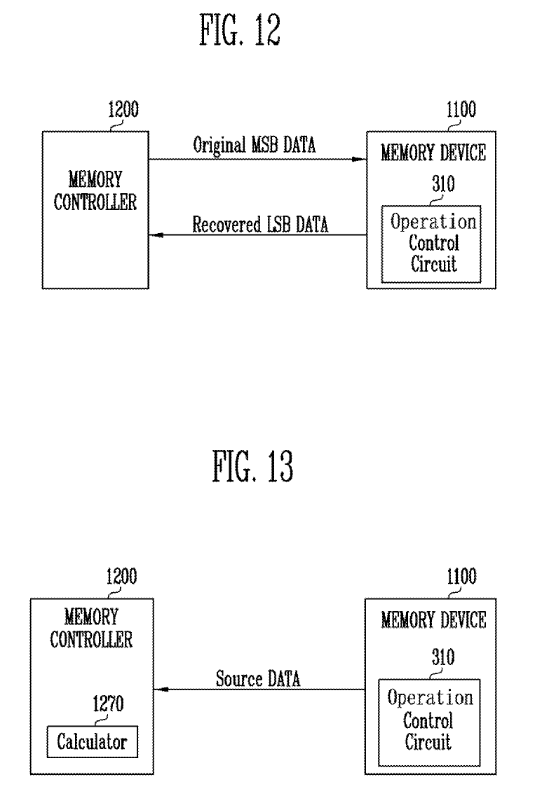

FIGS. 12 and 13 are diagrams illustrating embodiments of the memory controller 1200 and the memory device 1100 according to an embodiment.

FIG. 12 illustrates an embodiment of a memory system in which the above-described data recovery algorithm is performed in the memory device 1100, and FIG. 13 illustrates an embodiment of the memory system in which the above-described data recovery algorithm is performed in the memory controller 1200.

Referring to FIGS. 11 and 12, the memory device 1100 may perform all logical operations so as to store the LSB data. The memory device 1100 may include the operation control circuit 310. The operation control circuit 310 may be included in the control logic 300 of FIG. 3 and output the page buffer control signals PBSIGNALS so that an XOR operation may be performed in the page buffers PB1 to PBI of FIG. 3.

After the memory device 1100 generates the source DATA \textcircled{3}, the memory controller 1200 may transfer the Original MSB DATA \textcircled{4} to the memory device 1100. The memory device 1100 may recover the LSB data \textcircled{5} by using the Original MSB DATA \textcircled{4} received from the memory controller 1200 and transfer the recovered LSB data \textcircled{5} to the memory controller 1200. In an embodiment, for example, the recovered LSB data may be stored in the first latches of the page buffers PB1 to PBI. For example, the read data of step S810 may be erased from the first latches prior to storing the recoved LSB data within the first latches.

Differently from FIG. 12, as illustrated in FIG. 13, the memory controller 1200 may perform some logical operations for a data recovery operation.

Referring to FIGS. 11 and 13, the memory device 1100 may generate the source DATA \textcircled{3} and may transfer the source DATA \textcircled{3} to the memory controller 1200. The memory controller 1200 may recover the LSB data \textcircled{5} by performing a logical operation of the Original MSB DATA \textcircled{4} stored therein and the source DATA \textcircled{3} received from the memory device 1100. The memory controller 1200 may separately include the logical operation circuit 1270 (i.e., calculator). The logical operation circuit 1270 may generate the recovered LSB data \textcircled{5} by performing an XOR operation of the Original MSB DATA \textcircled{4} and the source DATA \textcircled{3}.

The above-described data recovery operation may be applied to a single plane method or a multi plane method. This will be described with reference to FIGS. 14 to 17.

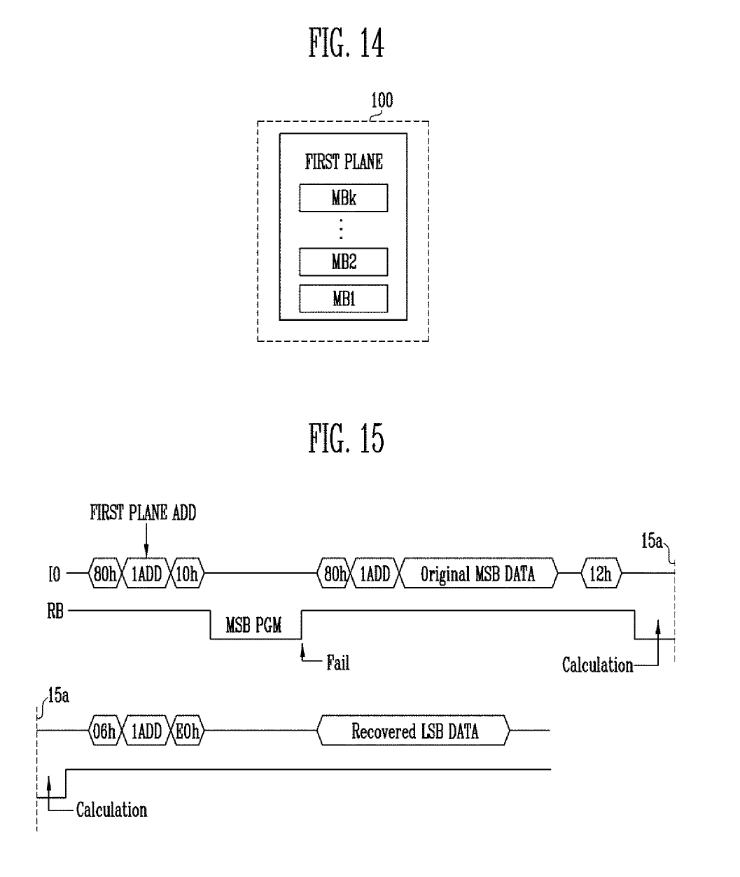

FIGS. 14 and 15 are diagrams illustrating a method of operating a memory system according to an embodiment. FIG. 14 illustrates the memory cell array 100 using a single plane method, and FIG. 15 illustrates a method of operating a memory system using a single plane method.

Referring to FIG. 14, the memory cell array 100 may include a first plane. The memory cell array 100 may include a plurality of planes in addition to the first plane. However, when the first plane is selected, the other planes may be unselected. Therefore, only the first plane will be described.

The first plane may include the plurality of memory blocks MB1 to MBk, and one of the plurality of memory blocks MB1 to MBk may be selected during a program operation.

Referring to FIG. 15, to perform the MSB program operation after the LSB program operation, the memory controller 1200 of FIG. 1 may sequentially transfer an input command 80h, a first address 1ADD including a first plane address, and a program command 10h to the memory device 1100 of FIG. 1 through the input/output lines IO. A ready/busy signal RB of the memory device 1100 may be maintained at a high level since the program operation is not performed yet. The memory device 1100 may perform a most significant bit program operation MSB PGM in response to the program command 10h. When the MSB program operation MSB PGM is performed, the ready/busy signal RB may be at a low level.

When the MSB program operation MSB PGM fails, the ready/busy signal RB may transition from low to high, and the memory controller 1200 may sequentially transfer the input command 80h, the first address 1ADD, the Original MSB DATA, and an operation command 12h to the memory device 1100. The memory device 1100 may perform an XOR operation for a data recovery operation in response to the operation command 12h. The ready/busy signal RB may be at a low level when the XOR operation is performed.

When the LSB data is recovered by the XOR operation, the memory controller 1200 may sequentially transfer a setup command 06h, the first address 1ADD, and an output command E0h to the memory device 1100. The memory device 110 may output the recovered LSB DATA to the memory controller 1200 in response to the output command E0h.

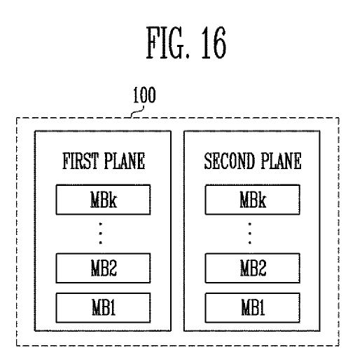

FIGS. 16 and 17 are diagrams illustrating a method of operating a memory system according to an embodiment.

FIG. 16 illustrates the memory cell array 100 using a multi plane method, and FIG. 17 illustrates a method of operating a memory system using a multi plane method.

Referring to FIG. 16, the memory cell array 100 may include first and second planes. Although the memory cell array 100 may include a plurality of planes in addition to the first and second planes, an example in which the first and second planes are selected and the other planes are unselected will be described in this embodiment.

Each of the first and second planes may include the plurality of memory blocks MB1 to MBk, and one of the plurality of memory blocks MB1 to MBk may be selected from each of the first and second planes during a program operation.

Referring to FIG. 17, when the LSB program operation of a selected memory block of each of the first and second planes is completed, the memory controller 1200 of FIG. 1 may sequentially transfer the input command 80h for a program operation of the first plane, the first address 1ADD including the first plane address, and a standby command 11h to the memory device 1100 of FIG. 1, and may sequentially transfer the input command 80h for a program operation of the second plane, a second address 2ADD including a second plane address, and the program command 10h to the memory controller 1100 of FIG. through the input/output lines Its so as to perform the MSB program operation. The ready/busy signal RB of the memory device 1100 may be maintained at a high level since the program operation is not performed yet. The memory device 1100 may perform the MSB program operation MSB PGM on the selected memory blocks of the first and second planes in response to the program command 10h. When the MSB program operation MSB PGM is performed, the ready/busy signal RB may be at a low level.

When the MSB program operation MSB PGM fails in the at least one of the first and second planes, the ready/busy signal RB may transition from low to high, and the memory controller 1200 may sequentially transfer the input command 80h, the first address 1ADD, the Original MSB DATA to be programmed into the selected memory block of the first plane, and a standby command 11h to the memory device 1100, and may sequentially transfer the input command 80h, the second address 2ADD, the Original MSB DATA to be programmed into the selected memory block of the second plane, and the operation command 12h to the memory device 1100.

The memory device 1100 may perform a logical operation for a data recovery operation for each of the first and second planes in response to the operation command 12h. The ready/busy signal RB may be at a low level when the logical operation is performed.

When the LSB data of each of the first and second planes is recovered by the logical operation, the memory controller 1200 may sequentially transfer the setup command 06h, the first address 1ADD, and an output command E0h to the memory device 1100, and the memory device 1100 may output the recovered LSB data recovered in the first plane to the memory controller 1200 in response to the output command E0h. Subsequently, the memory controller 1200 may sequentially transfer the setup command 06h, the second address 2ADD, and the output command E0h to the memory device 1100, and the memory device 1100 may output the recovered LSB data in the second plane to the memory controller 1200 in response to the output command E0h.

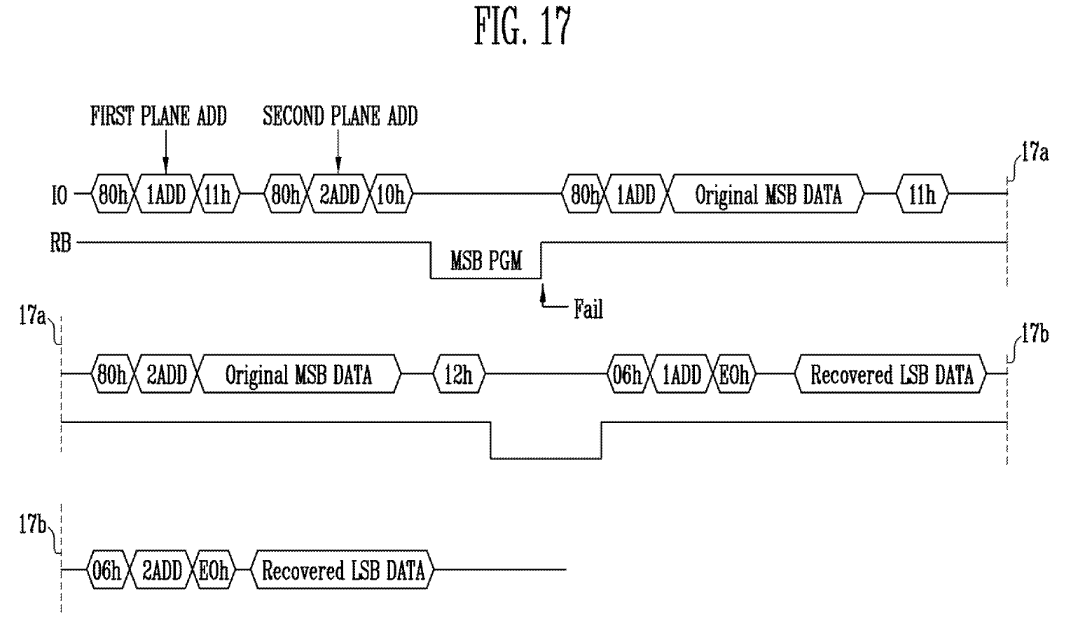

FIG. 18 is a flowchart illustrating an embodiment of a program operation order according to an embodiment.

Referring to FIG. 18, when a memory device is a die, a first die may include a plurality of planes. For example, the first die may include first and second planes. Program operations of the selected memory blocks of the first and second planes may be performed according to a predetermined order. For example, a program operation may be performed in units of a most significant bit (MSB) page and a less significant bit (LSB) page in the selected memory blocks, and a program order may be set by various methods to reduce interference between different physical pages PG1 to PG4, . . . . For example, a LSB program of the first physical page PG1 may be first programmed in the selected memory block of the first plane (0), and a LSB program of the first physical page PG1 may be performed in the selected memory block of the second plane (1). Hereinafter, for convenience of explanation, the selected memory block is omitted, and the first plane and the second plane will be described.

After a LSB program of the second physical page PG2 of the first plane is performed, a LSB program of the second physical page PG2 of the second plane may be performed (3). Subsequently, a MSB program of the first plane may be performed (4), and the MSB program of the second plane may be performed (5). In other words, on the basis of the selected physical page, after the LSB program is first performed on the selected physical page, a LSB program of another physical page may be performed, and a MSB program of the selected physical page may be subsequently performed. In this manner, the LSB and MSB programs of the first and second planes may be performed.

For example, when the MSB program operation of the third physical page of the first plane fails, the LSB data of the third physical page may be recovered. When the program operation is performed according to a program order of FIG. 18, the LSB data performed prior to six steps (6) may be recovered. When the LSB data and the MSB data used at all six steps of the program operation of the memory controller 1200 of FIG. 1 are stored, the capacity of the storage device of the memory controller 1200 may be significantly increased.

However, when the algorithm according to the above-described embodiment is applied, the memory controller 1200 may not store the LSB data until the MSB program of the selected physical page is completed, so that the size of the memory controller 1200 may be reduced.

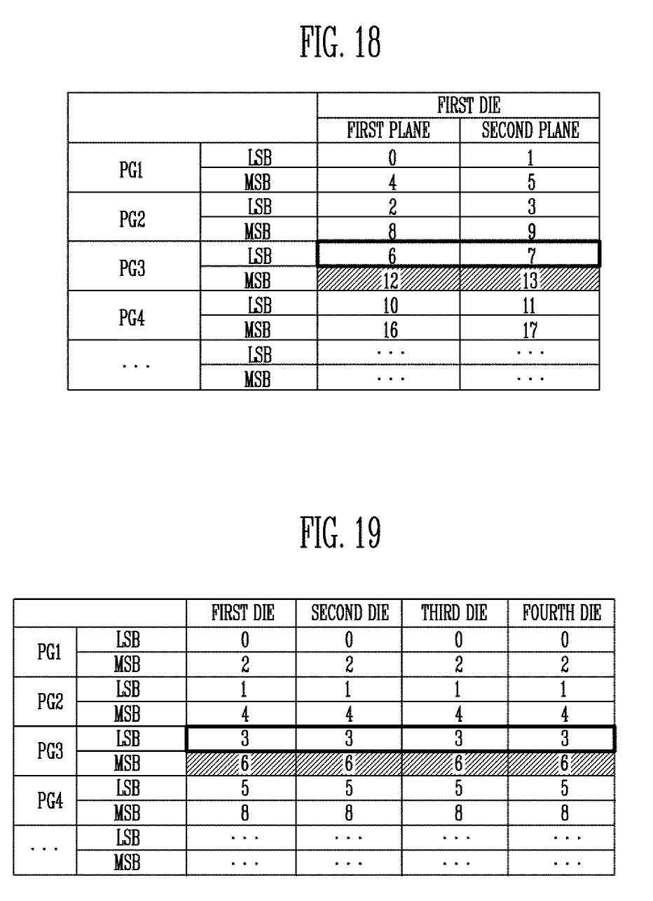

FIG. 19 is a flowchart illustrating an embodiment of a program operation order according to an embodiment.

Referring to FIG. 19, the memory controller 1200 of FIG. 1 may control a plurality of memory devices. For example, a plurality of channels may be coupled to the memory controller 1200, and a plurality of dies may be coupled to the respective channels. Dies coupled to different channels may operate simultaneously in response to control of the memory controller 1200, and dies coupled to the same channel may be performed in units of dies.

For example, when first to fourth dies are coupled to four channels, selected memory blocks of the first to fourth dies may be programmed at the same time. A program operation may be performed in units of pages according to a predetermined order in the selected memory blocks of the first to fourth dies.

For example, a program operation may be performed in units of a most significant bit (MSB) page and a less significant bit (LSB) page in the selected memory blocks, and a program order may be set by various methods to reduce interference between different physical pages PG1 to PG4, . . . .

For example, the LSB program of the first physical page PG1 may be first programmed in the selected memory blocks of the first to fourth dies, and the LSB program of the second physical page PG2 may be performed in the selected memory blocks of the first to fourth dies (1). Hereinafter, for convenience of explanation, the selected memory blocks are omitted, and the first to fourth dies will be described.

After the MSB program of the first physical page PG1 of each of the first to fourth dies is performed, the LSB program of the third physical page PG3 of each of the first to fourth dies may be performed (3). Subsequently, the MSB program of the second physical page PG2 of each of the first to fourth dies may be performed (4), and the LSB program of the fourth physical page PG4 of each of the first to fourth dies may be performed (5). In other words, on the basis of the selected physical pages, after an LSB program is first performed on the selected physical pages, an LSB program of other physical pages may be performed, and an MSB program of the selected physical pages may be subsequently performed. In this manner, the LSB and MSB programs of the first to fourth dies may be performed.

For example, when the MSB program operation of the third physical pages PG3 of the first to fourth dies fails, the LSB data of the third physical pages PG3 may be recovered. When the program operation is performed according to a program order of FIG. 19, the LSB data performed prior to three steps (6) may be recovered. When the LSB data and the MSB data used at the three steps of the program operation are stored in the memory controller 1200 of FIG. 1, the capacity of the storage device of the memory controller 1200 may be significantly increased. In addition, as the number of dies increases, the memory controller 1200 may require a storage device with a higher capacity.

However, when the algorithm according to the above-described embodiment is applied, the memory controller 1200 may not store the LSB data until the MSB program of the selected physical pages is completed, so that the size of the memory controller 1200 may be reduced.

FIG. 20 is a diagram illustrating an embodiment of the memory system including the memory controller 1200 illustrated in FIG. 2.

Referring to FIG. 20, a memory system 30000 may be embodied into a cellular phone, a smart phone, a tablet PC, a personal digital assistant (PDA), or a wireless communication device. The memory system 30000 may include the memory device 1100 and the memory controller 1200 controlling the operations of the memory device 1100. The memory controller 1200 may control a data access operation of the memory device 1100, for example, a program operation, an erase operation or a read operation in response to control of a processor 3100.

The memory controller 1200 may control data programmed into the memory device 1100 to be output through a display 3200.

A radio transceiver 3300 may exchange a radio signal through an antenna ANT. For example, the radio transceiver 3300 may change the radio signal received through the antenna ANT into a signal which can be processed by the processor 3100. Therefore, the processor 3100 may process the signal output from the radio transceiver 3300 and transfer the processed signal to the memory controller 1200 or the display 3200. The memory controller 1200 may program the signal processed by the processor 3100 into the semiconductor memory device 1100. In addition, the radio transceiver 3300 may change a signal output from the processor 3100 into a radio signal, and output the radio signal to an external device through the antenna ANT. A control signal for controlling the operations of the processor 3100 or data to be processed by the processor 3100 may be input by the input device 3400, and the input device 3400 may include a pointing device, such as a touch pad and a computer mouse, a keypad, or a keyboard. The processor 3100 may control the operations of the display 3200 so that data output from the memory controller 1200, data output from the radio transceiver 3300, or data output from the input device 3400 may be output through the display 3200.

According to an embodiment, the memory controller 1200 controlling the operations of the memory device 1100 may form part of the processor 3100, or be formed as a separate chip from the processor 3100.

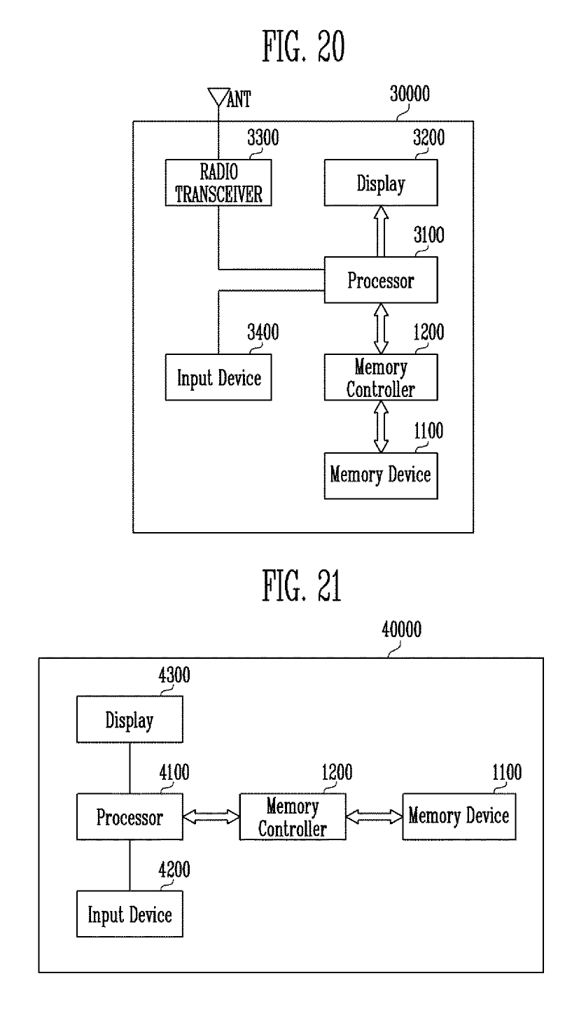

FIG. 21 is a diagram illustrating an embodiment of the memory system including the memory controller as illustrated in FIG. 2.

Referring to FIG. 21, a memory system 40000 may be embodied into a personal computer (PC), a tablet PC, a net-book, an e-reader, a personal digital assistant (PDA), a portable multimedia player (PMP), an MP3 player, or an MP4 player.

The memory system 40000 may include the memory device 1100 and the memory controller 1200 controlling the operations of the memory device 1100.

A processor 4100 may output data stored in the memory device 1100 through a display 4300 according to data input through an input device 4200. Examples of the input device 4200 may include a pointing device such as a touch pad or a computer mouse, a keypad, or a keyboard.

The processor 4100 may control the general operations of the memory system 40000 and control the operations of the memory controller 1200. According to an embodiment, the memory controller 1200 controlling the operations of the memory device 1100 may be part of the processor 4100, or be formed as a separate chip from the processor 4100.

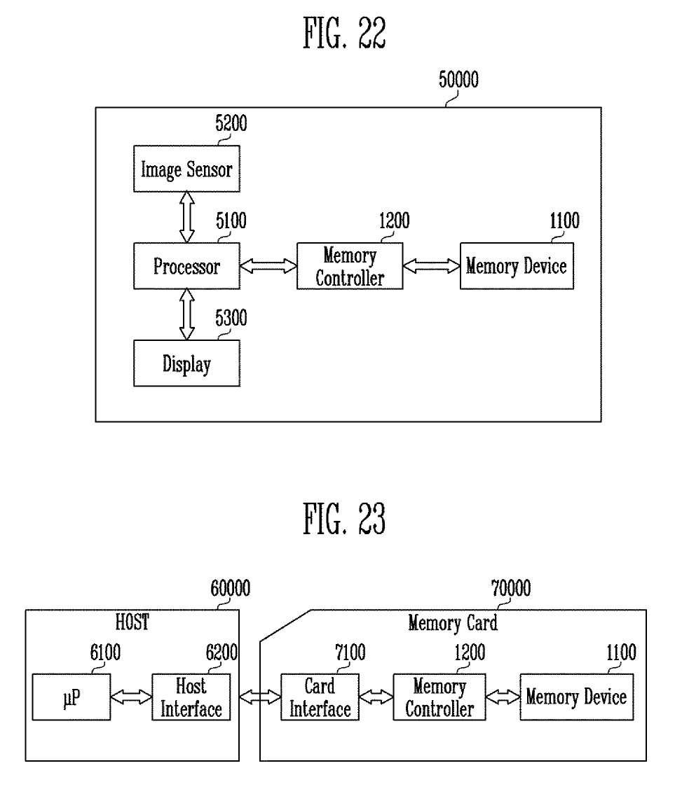

FIG. 22 is a diagram illustrating an embodiment of the memory system including the memory controller 1200 as illustrated in FIG. 2.

Referring to FIG. 22, a memory system 50000 may be embodied into an image processor, for example, a digital camera, a cellular phone with a digital camera attached thereto, a smart phone with a digital camera attached thereto, or a table PC with a digital camera attached thereto.

The memory system 50000 may include the memory device 1100 and the memory controller 1200 controlling a data processing operation of the memory device 1100, for example, a program operation, an erase operation or a read operation.

An image sensor 5200 of the memory system 50000 may convert an optical image into digital signals, and the converted digital signals may be transferred to the processor 5100 or the memory controller 1200. In response to control of the processor 5100, the converted digital signals may be output through the display 5300 or stored in the memory device 1100 through the memory controller 1200. In addition, the data stored in the memory device 1100 may be output through the display 5300 according to control of the processor 5100 or the memory controller 1200.

According to an embodiment, the memory controller 1200 controlling the operations of the memory device 1100 may be part of the processor 5100, or be formed as a separate chip from the processor 5100.

FIG. 23 is a diagram illustrating an embodiment of the memory system including the memory controller as illustrated in FIG. 2.

Referring to FIG. 23, a memory system 70000 may include a memory card or a smart card. The memory system 70000 may include the memory device 1100, the memory controller 1200, and a card interface 7100.

The memory controller 1200 may control a data exchange between the memory device 1100 and the card interface 7100. In an embodiment, the card interface 7100 may be a secure digital (SD) card interface or a multi-media card (MMC) interface, but it is not limited thereto.

The card interface 7100 may interface a data exchange between a host 60000 and the memory controller 1200 according to a protocol of the host 60000. According to an embodiment, the card interface 7100 may support a Universal Serial Bus (USB) protocol and an InterChip (IC)-USB protocol. The card interface 7100 may refer to hardware that supports a protocol used by the host 60000, software mounted on the hardware, or a signal transmission method.

When the memory system 70000 is connected to an host interface 6200 of the host 60000 such as a PC, a tablet PC, a digital camera, a digital audio player, a cellular phone, console video game hardware, or a digital set-top pox, the host interface 6200 may perform data communication with the memory device 1100 through the card interface 7100 and the memory controller 1200 in response to control of a microprocessor (μP) 6100.

According to embodiments, a program operation may be easily performed by recovering previously programmed data when the program operation fails.

In addition, according to embodiments, since a memory controller does not store data, programmed in a previous program operation, in a subsequent program operation, the size of the memory controller may be reduced.

An embodiment, for example, provides a new operating method and circuits for implementing the same in line with a changed structure of a memory array to increase the degree of integration, thereby increasing operating characteristics and reliability.

What is claimed is:

1. A memory system, comprising:
a memory controller sequentially transferring a program command, an address, a first logical page data and a second logical page data to a memory device, the memory controller temporarily storing original data of the first or second logical page data until a program operation of the first and second logical page data is completed,
wherein the memory device comprises:
a memory block including a plurality of physical pages into which the first and second logical page data are sequentially programmed;
a first latch reading and temporarily storing programmed logical page data from a selected physical page when the program operation of the second logical page data fails during a program operation of the selected physical page, among the physical pages;
a second latch temporarily storing the second logical page data; and
an operation unit performing an operation of the programmed logical page data stored in the first latch and the second logical page data stored in the second latch to generate source data, and performing an operation of the source data and the original data to recover the first logical page data.

2. The memory system of claim 1, wherein the memory controller temporarily stores the original data of the first or second logical page data.

3. The memory system of claim 1, wherein the operation unit performs an XOR operation of the programmed logical page data stored in the first latch and the second logical page data stored in the second latch to generate the source data, and
the operation unit performs an XOR operation of the source data and the original data to recover the first logical page data.

4. A memory system, comprising:
a memory device including a physical page configured to store least significant bit (LSB) data and most significant bit (MSB) data, store the LSB data in page buffers coupled to the physical page and perform a logical operation with the LSB data and the MSB data, and recover the LSB data; and
a memory controller configured to transfer commands to the memory device to recover the LSB data after a MSB program operation for programming the MSB data in the physical page

5. The memory system of claim 4, wherein the memory device comprises:
a memory block including the physical page; and
a control logic configured to control the page buffers to perform the logical operation with the LSB data and the MSB data in response to the commands,
wherein the page buffers coupled to the physical page are configured to store the MSB data.

6. The memory system of claim 5, wherein the logical operation is an XOR operation, and
the control logic includes an operation control circuit configured to control the page buffers to perform the XOR operation.

7. The memory system of claim , wherein the control logic controls the page buffers to:
read the data stored in the physical page and store read data in the page buffers before the MSB data is programmed in the physical page,
perform the logical operation of the MSB data stored in the page buffers and the read data to generate and store source data in the page buffers, and
receive original data of the MSB data and recover the LSB data by performing a logical operation with the original data of the MSB data and the source data.

8. The memory system of claim 7, wherein the page buffers comprise:
first latches configured to store the read data or recovered LSB data;
second latches configured to initially store the MSB data and then store the source data in place of the MSB data after the source data is generated; and
third latches configured to receive and store the original data of the MSB data.

9. The memory system of claim 4, wherein the memory controller transfers an input command, an address, original data of the MSB data and an operation command to the memory device when a program operation of the MSB data in the physical page fails.

10. The memory system of claim 9, wherein the memory device recovers the LSB data by performing the logical operation using the data stored in the physical page and the MSB data in response to the operation command, and outputs recovered LSB data to the memory controller in response to the output command transferred from the memory controller.

11. The memory system of claim 4, wherein when the LSB data is recovered, the memory device re-performs the MSB program operation by combining recovered LSB data with the MSB data.

12. A method of operating a memory system, the method comprising:
performing a least significant bit (LSB) program operation to program a selected physical page with LSB data;
reading the physical page and storing the LSB data;
performing a most significant bit (MSB)program operation to program the selected physical page with MSB data;
generating source data by performing a logical operation of the LSB data and the MSB data when the MSB program operation fails; and
recovering the LSB data by performing a logical operation with original data of the MSB data and the source data.

13. The method of claim 12, further comprising erasing the LSB data stored in the memory controller when the LSB program operation is completed.

14. The method of claim 12, wherein in the storing of the LSB data, the LSB data is stored in page buffers of the memory device.

15. The method of claim 12, wherein during the MSB program operation, the MSB data is stored in the memory controller.

16. The method of claim 15, wherein after the MSB program operation fails the source data is stored in the memory controller after the MSB data is erased.

17. The method of claim 12, wherein the LSB program operation of the selected physical page is terminated when the MSB program operation passes.

18. The method of claim 12, wherein the logical operation is an XOR operation.

19. The method of claim 12, wherein the original data of the MSB data is stored in the memory controller.

20. The method of claim 12, further comprising re-performing the MSB program operation by combining recovered LSB data with the MSB data when the LSB data is recovered.

21. A method of operating a memory system, comprising:
in a program operation during which selected memory cells are maintained at an erase state, or are programmed to a first program state, a second program state, or a third program state, p1 performing an least significant bit (LSB) program operation to increase threshold voltages of memory cells to be programmed into the second and third program states;
performing an most significant bit (MSB) program operation to increase threshold voltages of memory cells to be programmed into the first to third program states;
generating source data by inverting data corresponding to the erase state and the first program state from the MSB data used in the MSB program operation when the MSB program operation fails; and
recovering LSB data by performing a logical operation of the source data and original data of the MSB data.

22. The method of claim 21, wherein the generating of the source data comprises:
reading the memory cells on which the LSB program operation is performed, and temporarily storing the LSB data; and
preforming an XOR operation of the LSB data and the MSB data.

23. The method of claim 21, wherein the recovering of the LSB data comprises performing an XOR operation of the source data and the original data of the MSB data.
